(19) United States
(12) Patent Application Publication
(10) Pub. No.: US 2023/0253404 A1
(43) Pub. Date: Aug. 10, 2023

(54) TECHNOLOGIES FOR SELECTIVE SOURCE AND DRAIN EPITAXIAL GROWTH

(71) Applicant: Tokyo Electron Limited, Tokyo (JP)

(72) Inventors: Mark I. Gardner, Albany, NY (US); H. Jim Fulford, Albany, NY (US)

(21) Appl. No.: 17/668,632

(22) Filed: Feb. 10, 2022

(51) Int. Cl. H01L 27/092; H01L 29/423; H01L 27/06; H01L 29/45; H01L 21/8238; H01L 21/822

(52) U.S. Cl. CPC H01L 27/092; H01L 29/42392; H01L 27/0688; H01L 29/458; H01L 21/823814; H01L 21/8221

(57) ABSTRACT

Technologies for making a complementary field effect transistor (CFET) semiconductor devices using selective source and drain epitaxial growth are described. The CFET semiconductor devices can be made using substantially uniformly-doped epitaxial layers to create self-aligned, selective epitaxial extensions that can be used as the source/drain regions in the transistor structures. Other embodiments are disclosed.

### BACKGROUND

This application generally relates to methods for making semiconductor devices. In particular, this application relates to methods for making a complementary field effect transistor (CFET) semiconductor device using selective source and drain epitaxial growth.

FIELD OF THE DISCLOSURE

Integrated circuits are widely used in the electronics industry to provide electronic devices such as smart phones, computers, and the like. Integrated circuits (ICs) may include many semiconductor devices, such as transistors, capacitors and the like, which are interconnected by wiring on a semiconductor substrate. There is an ever increasing demand for smaller and faster ICs that support a greater number of complex functions for electronic devices. This demand has led to the semiconductor manufacturing industry scaling down the area of ICs on the substrate, while also improving performance and power consumption efficiencies for the IC.

In the manufacture of a semiconductor ICs (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors of the IC have been created in one plane, with wiring/metallization of the IC formed above the active device plane, and have thus been characterized as two-dimensional (2D) circuits or 2D fabrication. Scaling efforts have greatly increased the number of transistors per unit area in 2D circuits, which has enabled the integration of heterogeneous functional circuits, such as logic and memory circuits, onto the same semiconductor substrate. However, 2D scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other as another means of further scaling of ICs.

### SUMMARY

This application describes methods for making a semiconductor device using selective source and drain epitaxial growth. In some embodiments, the methods comprise growing a first epitaxial layer over a substrate, growing a second epitaxial layer over the first epitaxial layer, the second epitaxial layer having an oxidation rate different than the first epitaxial layer, exposing a sidewall of the first and second epitaxial layers, growing a first epitaxial extension on the sidewall of the first epitaxial layer while insulating the sidewall of the second epitaxial layer, growing a second epitaxial extension on the sidewall of the second epitaxial layer while insulating the sidewall of the first epitaxial layer, forming a contact on the first epitaxial extension, and then forming a contact on the second epitaxial extension. In other embodiments, the methods include growing a first epitaxial layer over a substrate, the first epitaxial layer comprising a first conductivity type dopant and a first semiconducting material, growing a second epitaxial layer over the first epitaxial layer, the second epitaxial layer comprising a second semiconducting material different from the first semiconducting material or a second conductivity type dopant different from the first conductivity type dopant, exposing a sidewall of the first and second epitaxial layers, growing a first epitaxial extension on the sidewall of the first epitaxial layer while insulating the sidewall of the second epitaxial layer, growing a second epitaxial extension on the sidewall of the second epitaxial layer while insulating the sidewall of the first epitaxial layer, forming a contact on the first epitaxial extension, and then forming a contact on the second epitaxial extension. In yet other embodiments, the methods comprise growing a stack of epitaxial layers over a substrate, wherein the stack of epitaxial layers includes a first epitaxial layer and a second epitaxial layer over the first epitaxial layer, the second epitaxial layer having an oxidation rate different than the first epitaxial layer, depositing an isolation barrier around the stack of epitaxial layers to cover at least a sidewall of each epitaxial layer of the stack of epitaxial layers, removing a portion of the isolation barrier to expose the sidewalls of the epitaxial layers in the stack of epitaxial layers, differentially growing a dielectric on the sidewall of the first epitaxial layer and the second epitaxial layer, removing the dielectric from the sidewall of the first epitaxial layer, growing a first epitaxial extension on the sidewall of the first epitaxial layer, removing the dielectric from the sidewall of the second epitaxial layer after growing the first epitaxial extension, growing a second epitaxial extension on the sidewall of the second epitaxial layer, forming a first salicide layer on the first epitaxial extension and a second salicide layer on the second epitaxial extension, forming first source and drain contacts to the first salicide and forming second source and drain contacts to the second salicide, and then depositing a first gate metal to form a first transistor and depositing a second gate metal to form a second transistor over the first transistor.

In these methods, the first epitaxial layer can comprise a first conductivity type dopant and a first semiconducting material and the second epitaxial layer can comprise a second semiconducting material different from the first semiconducting material or a second conductivity type dopant different from the first conductivity type dopant. The first epitaxial layer can comprise Si heavily doped with an n-type dopant and the second epitaxial layer can comprise Ge heavily doped with a p-type dopant. As well, a first sidewall dielectric layer can be grown on the sidewall of the first epitaxial layer and a second sidewall dielectric layer can be grown on the sidewall of the second epitaxial layer so that the first and second sidewall dielectric layers have a different size. The first sidewall dielectric layer can be removed from the first epitaxial layer prior to growing the first epitaxial extension, and then a high-K dielectric layer can be provided on the first epitaxial extension prior to growing the second epitaxial extension.

The methods include removing the high-K dielectric layer from the first epitaxial extension after growing the second epitaxial extension and then growing a first salicide on the first epitaxial extension and a second salicide on the second epitaxial extension. The methods also include depositing a first source metal and a first drain metal to connect with the first salicide and depositing a second source metal and a second drain metal to connect with the second salicide. The methods further include insulating the first and second epitaxial layers. The methods also include forming a first gate metal to create a first transistor comprising the first epitaxial layer and forming a second gate metal to create a second transistor comprising the second epitaxial layer that is located over the first transistor.

### BRIEF DESCRIPTION OF THE DRAWINGS

The concepts described herein are illustrated by way of example and not by way of limitation in the accompanying figures. For simplicity and clarity of illustration, elements illustrated in the figures are not necessarily drawn to scale. Where considered appropriate, reference labels have been repeated among the figures to indicate corresponding or analogous elements.

FIG. 1 is a cross-sectional view of at least one embodiment of a CFET semiconductor device stack fabricated using the selective source and drain epitaxial growth techniques disclosed herein;

FIGS. 2A-B are a simplified flow diagram of at least one embodiment of a method for manufacturing the CFET semiconductor device stack of FIG. 1;

FIG. 3 is a cross-sectional view of at least one embodiment of an epitaxial layer stack that may be fabricated during the performance of the method of FIG. 2;

FIG. 4 is a cross-sectional view of at least one embodiment of the epitaxial layer stack of FIG. 3 subsequent to an etching process during the performance of the method of FIG. 2;

FIG. 5 is a cross-section view of at least one embodiment of the epitaxial layer stack of FIG. 4 subsequent to an isolation layer deposition during the performance of the method of FIG. 2;

FIG. 6 is a cross-sectional view of at least one embodiment of the epitaxial layer stack of FIG. 5 subsequent to an etching process to expose sidewalls of the epitaxial layer stack during the performance of the method of FIG. 2;

FIG. 7 is a cross-sectional view of at least one embodiment of the epitaxial layer stack of FIG. 6 subsequent to a selective ident etching process of some of the layers of the epitaxial layer stack during the performance of the method of FIG. 2;

FIG. 8 is a cross-sectional view of at least one embodiment of the epitaxial layer stack of FIG. 7 subsequent to a selective dielectric growth process on the sidewalls of some of the layers of the epitaxial layer stack during the performance of the method of FIG. 2;

FIG. 9 is a cross-sectional view of at least one embodiment of the epitaxial layer stack of FIG. 8 subsequent to an etching process to remove one of the dielectric growths from a sidewall of a corresponding epitaxial layer of the epitaxial layer stack during the performance of the method of FIG. 2;

FIG. 10 is a cross-sectional view of at least one embodiment of the epitaxial layer stack of FIG. 7 subsequent to an alternative selective dielectric growth on the sidewalls of some of the layers of the epitaxial layer stack during the performance of the method of FIG. 2;

FIG. 11 is a cross-sectional view of at least one embodiment of the epitaxial layer stack of FIG. 9 or FIG. 10 subsequent to a selective epitaxial extension growth process and high-K dielectric growth process on an epitaxial layer of the epitaxial layer stack during the performance of the method of FIG. 2;

FIG. 12 is a cross-sectional view of at least one embodiment of the epitaxial layer stack of FIG. 11 subsequent a selective etching process to remove the dielectric growth a sidewall of another epitaxial layer of the epitaxial layer stack during the performance of the method of FIG. 2;

FIG. 13 is a cross-sectional view of at least one embodiment of the epitaxial layer stack of FIG. 12 subsequent to a selective epitaxial extension growth process on another epitaxial layer of the epitaxial layer stack during the performance of the method of FIG. 2;

FIG. 14 is a cross-sectional view of at least one embodiment of the epitaxial layer stack of FIG. 13 subsequent to a silicide selective salicide growth process on epitaxial extensions of the epitaxial layer stack during the performance of the method of FIG. 2;

FIG. 15 is a cross-sectional view of at least one embodiment of the epitaxial layer stack of FIG. 14 subsequent to a formation of metal contacts on the silicide layers of the epitaxial layer stack during the performance of the method of FIG. 2;

FIGS. 16 & 17 are cross-sectional views of at least one embodiment of the epitaxial layer stack of FIG. 15 subsequent to an epitaxial layer removal and high-K dielectric deposition process during the performance of the method of FIG. 2;

FIGS. 18 & 19 are cross-sectional views of at least one embodiment of the epitaxial layer stack of FIG. 17 subsequent to another epitaxial layer removal and metal deposition process during the performance of the method of FIG. 2;

FIGS. 20A & 20B are a simplified flow diagram of at least one embodiment of another method for manufacturing a CFET semiconductor device stack having multiple channels;

FIG. 21 is a cross-sectional view of at least one embodiment of an epitaxial layer stack of subsequent to several fabrication processes, including a selective dielectric growth process of the sidewall of several epitaxial layers, during the performance of the method of FIG. 20;

FIG. 22 is a cross-sectional view of at least one embodiment of the epitaxial layer stack of FIG. 21 subsequent to a salicide deposition process on corresponding epitaxial extensions of the epitaxial layer stack during the performance of the method of FIG. 20;

FIG. 23 is a cross-sectional view of at least one embodiment of the epitaxial layer stack of FIG. 22 subsequent to metallization processes during the performance of the method of FIG. 20; and

FIG. 24 is a cross-sectional view of at least one embodiment of a CFET semiconductor devices, with multiple transistors stacked vertically, that can be manufactured using the method of FIG. 20.

### DETAILED DESCRIPTION OF THE DRAWINGS

While the concepts of the present disclosure are susceptible to various modifications and alternative forms, specific embodiments thereof have been shown by way of example in the drawings and will be described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

References in the specification to “one embodiment,” “an embodiment,” “an illustrative embodiment,” etc., indicate that the embodiment described may include a particular feature, structure, or characteristic, but every embodiment may or may not necessarily include that particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described. Additionally, it should be appreciated that items included in a list in the form of “at least one A, B, and C” can mean (A); (B); (C): (A and B); (B and C); or (A, B, and C). Similarly, items listed in the form of “at least one of A, B, or C” can mean (A); (B); (C): (A and B); (B and C); or (A, B, and C).

The disclosed embodiments may be implemented, in some cases, in hardware, firmware, software, or any combination thereof. The disclosed embodiments may also be implemented as instructions carried by or stored on a transitory or non-transitory machine-readable (e.g., computer-readable) storage medium, which may be read and executed by one or more processors. A machine-readable storage medium may be embodied as any storage device, mechanism, or other physical structure for storing or transmitting information in a form readable by a machine (e.g., a volatile or non-volatile memory, a media disc, or other media device).

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features.

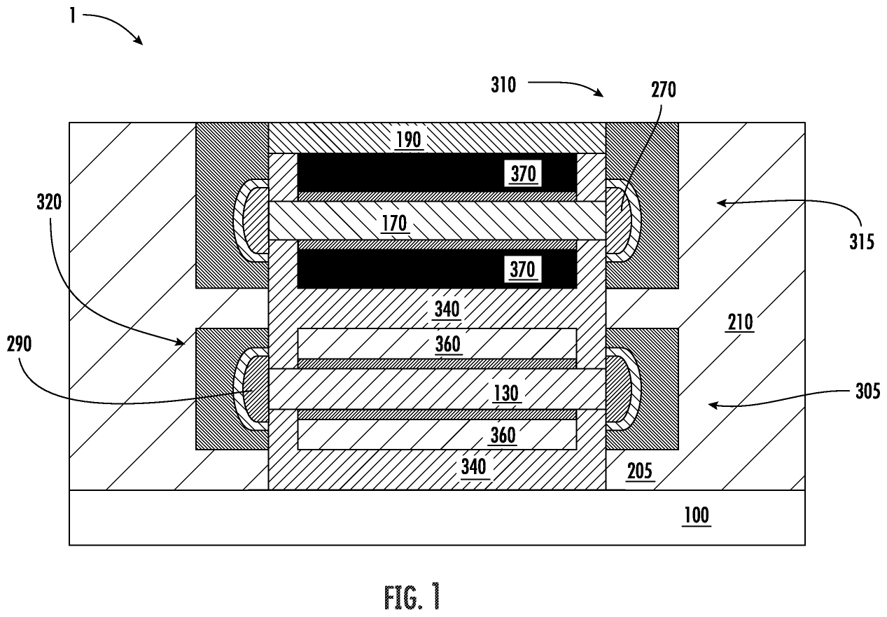

Referring now to FIG. 1, a complementary field effect transistor (CFET) structure 1 that can be manufactured using the technologies disclosed herein may include multiple semiconductor devices. For example, the illustrative CFET structure 1 includes a lower transistor 305 and an upper transistor 315 stacked on, or otherwise over, the lower transistor 305. Although shown as including on two CFETs in FIG. 1, it should be appreciated that, in other embodiments, the methodologies disclosed herein may be employed to fabricate a CFET structure having more than two transistors as discussed in more detail below.

As shown in FIG. 1, the lower transistor 305 and the upper transistor 315 are insulated from each other using dielectric 340 and isolation layer 210. The lower transistor 305 comprises an n+channel 130, gate metal 360, self-aligned source and drain extension regions 290, and metal contacts 320. The upper transistor 315 comprises a p+channel 170, gate metal 370, self-aligned source and drain extension regions 270, and metal contacts 310.

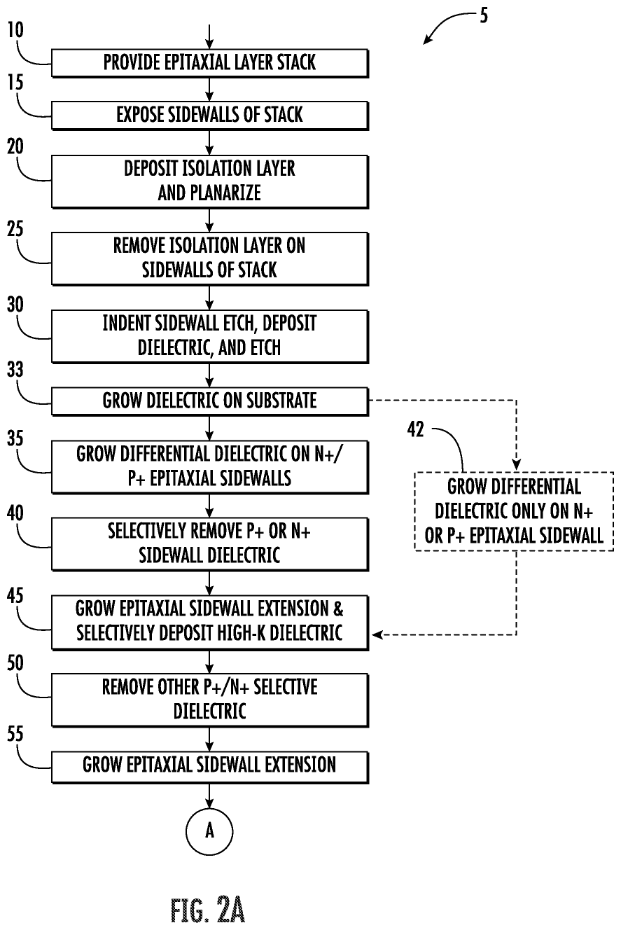

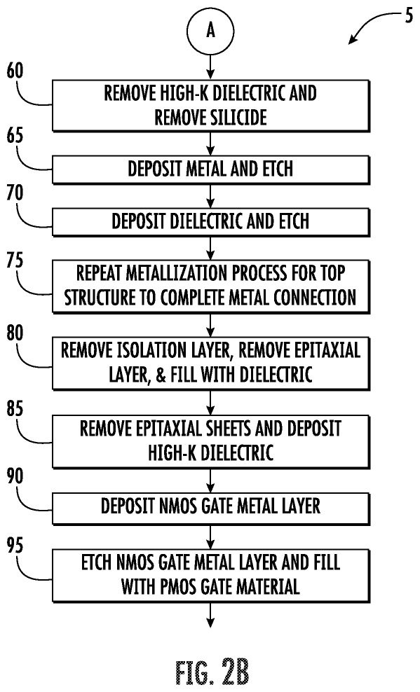

Referring now to FIGS. 2A and B, a method 5 for fabricating the CFET structure 1 of FIG. 1 is shown. The method 5 begins with block 10 in which an epitaxial layer stack 3 is fabricated or otherwise provided as shown in FIG. 3. The illustrative epitaxial layer stack includes a stack of epitaxial layers deposited on a substrate 100. The substrate 100 can be made of any known semiconducting material. Typical substrate materials include semiconductors, such as silicon (Si) and germanium (Ge), as well as other compounds that exhibit semiconducting properties. These semiconductor compounds can include group III-V and group II-VI compounds such as gallium arsenide (GaAs), gallium phosphide (GaP), and gallium nitride (GaN). Generally, the semiconductor substrate 100 includes bulk semiconductor substrates as well as substrates having deposited layers disposed thereon.

As shown in FIG. 3, a stack of epitaxial layers are sequentially deposited on the substrate 100. The illustrative stack of epitaxial layers includes a base epitaxial layer 110, an epitaxial layer 120, a highly-doped (n+) epitaxial layer 130, an epitaxial layer 140, another base epitaxial layer 150, epitaxial layer 160, another highly-doped (p+) epitaxial layer 170, an epitaxial layer 180, and a cap layer 190. All of the epitaxial layers of FIG. 3, except for 130 and 170, can be un-doped (or lightly doped) and are typically made of Si. In some configurations, the epitaxial layer 130 can be made of Si that has been heavily doped with an n+dopant and the epitaxial layer 170 can be made of Ge that has been heavily doped with a p+dopant. In some embodiments, the location of the epitaxial layers 130 and 170 can be switched. The epitaxial layers can be also made of other semiconducting materials, including group III-V and group II-VI compounds such as gallium arsenide (GaAs), gallium phosphide (GaP), and gallium nitride (GaN). The cap layer 190 comprises a dielectric material, such as a high-K dielectric material or SiN.

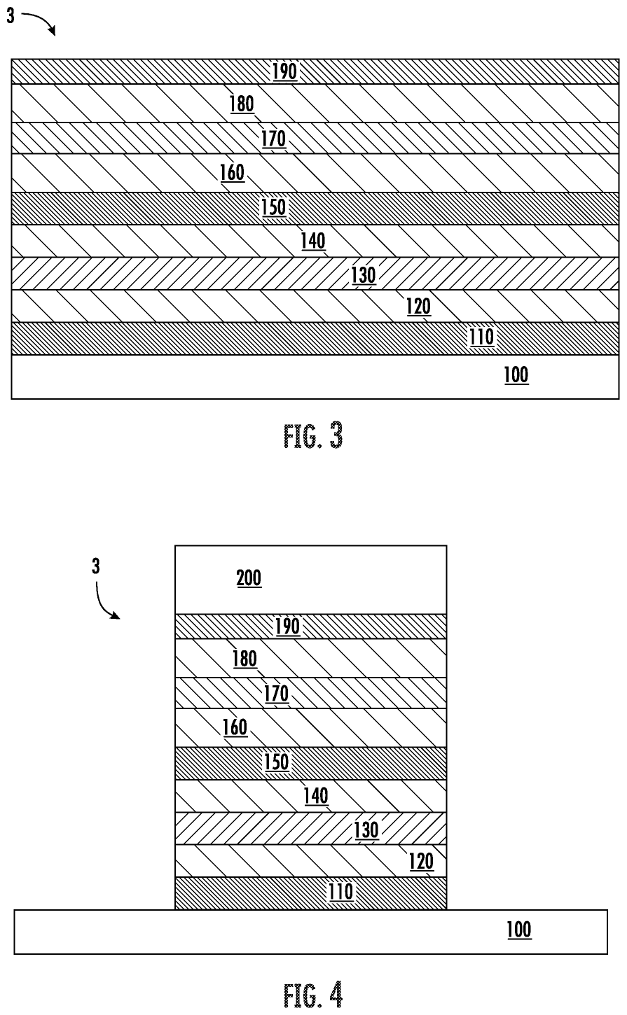

Referring back to FIG. 2A, after the epitaxial layer stack 3 has been provided in block 10, the method 5 continues with block 15 in which the sidewalls of the epitaxial layer stack 3 are exposed. To do so, a mask and etching process can be used to expose the sidewalls of the epitaxial layers of the epitaxial layer stack 3. For example, as shown in FIG. 4, a photoresist can be deposited on the cap layer 190 and patterned to create a mask layer 200. An anisotropic etching process can be used to remove any portions of these epitaxial layers that are not located under the mask layer 200. It should be appreciated that the anisotropic etching process does not remove any of the substrate 100 since it is used as an etch stop. Once the etching process is complete, the mask layer 200 can be removed.

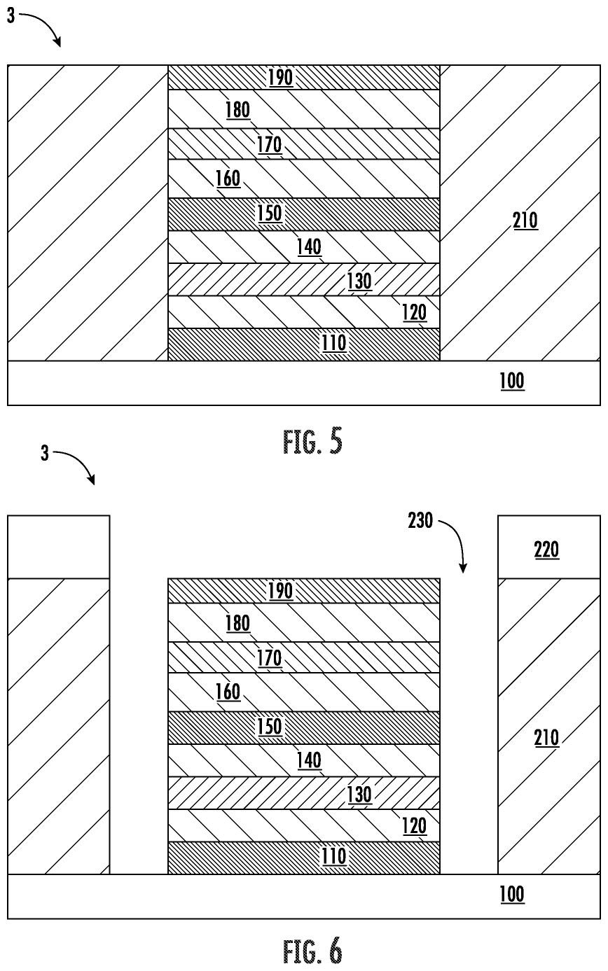

Referring back to FIG. 2A, after the mask and etching process of block 15, the method 5 continues with block 20 in which an isolation layer 310 is deposited on the entire structure of FIG. 4 and subsequently planarized to remove the isolation layer 310 above the cap layer 190 while leaving the isolation layer 210 on the sidewalls of the epitaxial layer to produce the epitaxial layer stack 3 shown in FIG. 5. In some embodiments, this planarization can be performed by chemical mechanical polishing (CMP).

Referring again back to FIG. 2A, after the isolation layering and planarization process of block 20, the method 5 continues with block 25 in which the isolation layer on the sidewalls of the epitaxial layer stack 3 are removed. The sidewalls of the stack of epitaxial layers are exposed so that further processing can be performed. To do so, another masking and etching process can be used to expose the sidewalls of the epitaxial layers. In this process, a photoresist (not shown) is deposited on the cap layer 190 and patterned to create a mask layer 220 as shown in FIG. 6. An anisotropic etching process can then be used to remove the isolation layer not under the mask 220. Again, it should be appreciated that the anisotropic etching process is stopped once it reaches the upper surface of the substrate 100. Once the etching process is complete, the mask layer 220 can be removed.

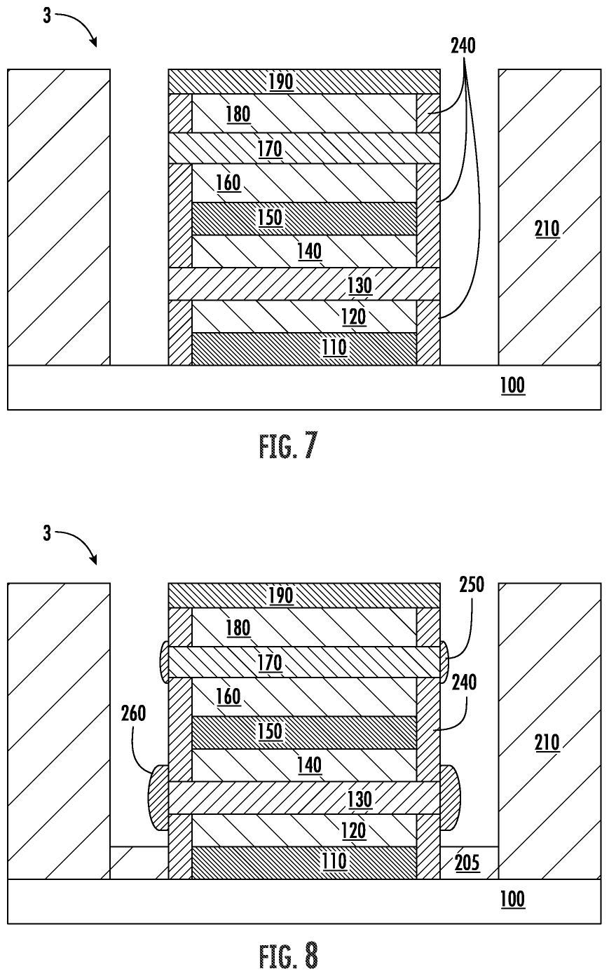

Referring back to FIG. 2A, after the isolation layer on the sidewalls of the epitaxial layer stack 3 has been removed in block 25, the method 5 continues with block 30 in which an indent etch is performed on the exposed sidewalls, followed by a dielectric deposition and an aligned etch. To do so, the sidewalls of the undoped (or lightly doped) epitaxial layers (110, 120, 140, 150, 160, and 180) can be laterally etched to form a recess between the sidewalls of the epitaxial layers (110, 120, 140, 150, 160, and 180) and highly-doped epitaxial layers 130, 170. This process can be performed using an isotropic etching process that is selective to the materials in the undoped or lightly-doped epitaxial layers. As shown in FIG. 7, this isotropic etch process does not remove any of the sidewalls of the highly-doped epitaxial layers 130, 170. After the indent etching process is complete, a dielectric layer can then deposited on the sidewalls of these epitaxial layers (110, 120, 140, 150, 160, and 180) and etched using the cap layer 190 to remove the undesired portions of the dielectric layer. The result of that deposition and etching process is the formation of sidewall dielectric layers 240, which are formed on the sidewalls of these epitaxial layers (110, 120, 140, 150, 160, and 180), as shown in FIG. 7.

Referring again back to FIG. 2A, after the indent etching process and dielectric deposition of block 30, the method 5 continues with block 33 in which a dielectric layer is grown on the upper surface of the substrate 100. That is, with the sidewall dielectric layers 240 formed, a bottom dielectric layer 205 is formed on the substrate 100 as shown in FIG. 8. In some embodiments, a dielectric layer can be deposited over the entire epitaxial layer stack 3 shown in FIG. 7. The dielectric layer is then planarized (by CMP) to remove any of the dielectric layer above the cap layer 190. Subsequently, a mask and etch process is used to remove any of that dielectric layer present while leaving the bottom dielectric layer 205 over the substrate 100 and between the isolation layer 210 and epitaxial layer 110. In other embodiments, the dielectric layer 205 can simply be grown on the exposed upper surface of the substrate 100 using any process that is selective to the substrate 100 material and that does not grow a dielectric layer on the sidewalls of epitaxial layers 130, 170.

Referring back to FIG. 2A, after the dielectric growth process of block 33, the method 5 continues with block 35 in which differentially-sized dielectric growth is performed on the doped epitaxial layers in the epitaxial layer stack 3. The sidewall dielectric layers are selectively grown on the highly-doped epitaxial layers 130 and 170. In the illustrative embodiment, the sidewall dielectric layers 250, 260 are selectively grown so that they have different sizes on the sidewalls. Such a selective growth is possible because the oxidation rate of the material and/or dopant in epitaxial layer 130 can be different than the oxidation rate of the material and/or dopant in epitaxial layer 170. For example, in the embodiments shown in FIG. 8, the sidewall dielectric layer 260 for epitaxial layer 130 can be grown to be larger than the sidewall dielectric layer 250 for epitaxial layer 170. In some embodiments, the oxidation rate can be different because of the materials (Si or Ge) used in these two epitaxial layers. In other embodiments, though, the oxidation rate can be different because of the dopant used (n or p) in these two epitaxial layers. In yet other embodiments, the oxidation rate can be different because a combination of these two factors (i.e., both dopant and material). For example, the oxidation rate of SiGe in one of the epitaxial layers 130, 170 can be about 1.5 to 2 times larger than the oxidation rate for Si in the other epitaxial layer.

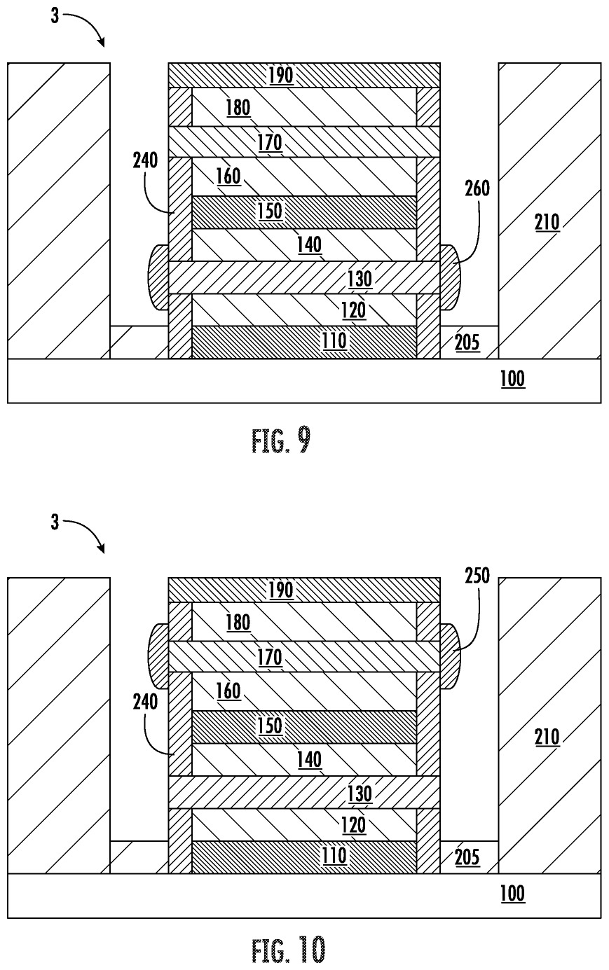

Referring yet again back to FIG. 2A, after the differentially-sized dielectric growth process of block 35, the method 5 continues with block 40 in which one of the differentially-sized dielectrics is removed. It should be appreciated that either of the sidewall dielectric layers (i.e., 250 or 260) can be removed in the process. In the illustrative embodiment of FIG. 9, the smaller sidewall dielectric layer 250 is removed to exposed the epitaxial layer 170. To do so, the removal process can be performed by an etching process that is selective to the dopant/material of the sidewall dielectric layer 250, which is different than the dopant/material of the sidewall dielectric layer 260.

Referring back to block 33 of the method 5 of FIG. 2A and alternative to blocks 35 and 40, the method 5 may continue from block 33 to block 42 in which an epitaxial extension is grown on one of the doped epitaxial layers without growing an extension on the other doped epitaxial layer. In this alternate process, rather than selectively growing both of the sidewall dielectric layers 250, 260 and then removing one of them by etching, a single sidewall dielectric layer 250 is grown without growing the other sidewall dielectric layer 260, as shown in FIG. 10. Again, this selective growth process can be performed based on the materials used in epitaxial layers 130 and 170.

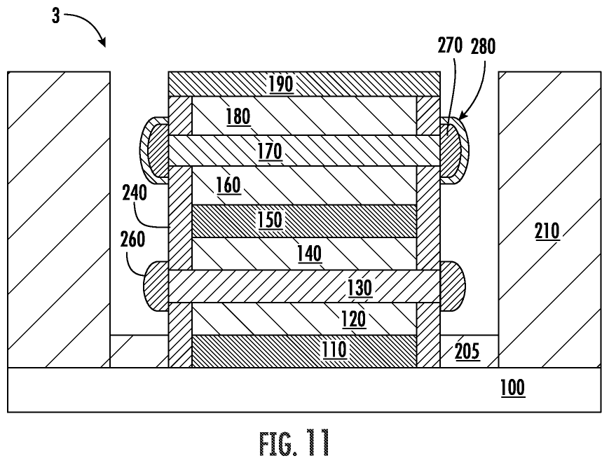

Referring again back to FIG. 2A, after the removal of one of the sidewall dielectrics in block 40 or after the selective epitaxial extension growth process of block 33, the method 5 continues to block 45. In block 45, an epitaxial extension is grown on the doped epitaxial layer followed by selective deposition of a high-K dielectric on the epitaxial extension. It should be appreciated that the epitaxial extension can be grown on the sidewall of either of the epitaxial layers 130 or 170, depending on which epitaxial layer has its sidewall presently exposed due to prior processing. For example, in the illustrative embodiments of FIG. 11, an epitaxial extension 270 is grown on the exposed sidewall of epitaxial layer 170. Of course, for epitaxial layer stack 3 of FIG. 10, the epitaxial extension could be grown on the sidewall of epitaxial layer 130 since it is presently exposed. Once the epitaxial extension has been formed, a high-K dielectric layer 280 can be selectively deposited on just that particular epitaxial extension 270. It should be appreciated that the high-K dielectric deposition is selective in that it does not adhere to the dielectric layers 240, 260. In some embodiments, the epitaxial extension 270 can be made of SiAs, SiP, SiB, SiGeB, GeB, GeSnB, or combinations thereof, and can be the same as—or different from—the material used in epitaxial layer 170.

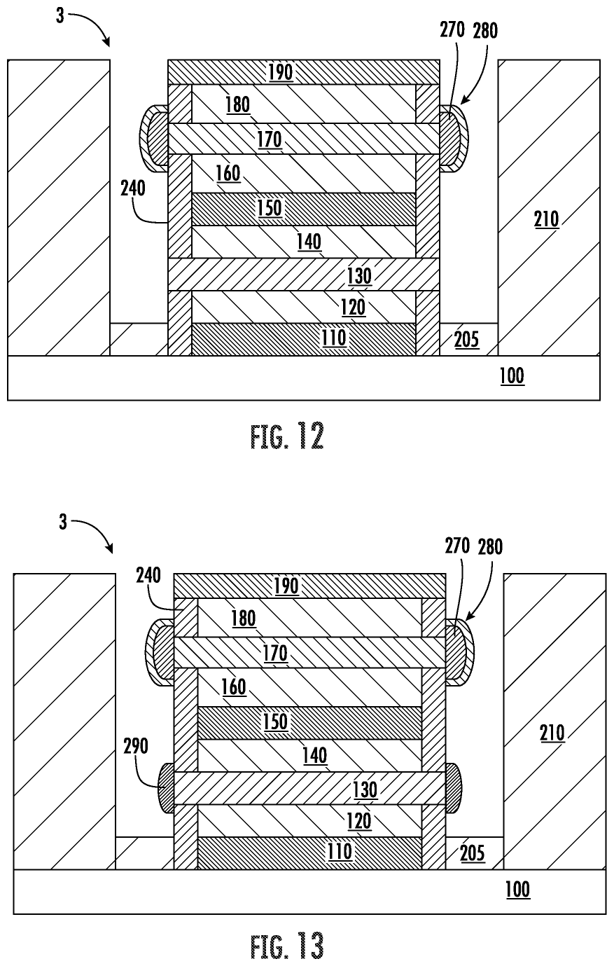

Referring back to FIG. 2A, after the epitaxial extension growth and high-K dielectric deposition processes of block 45, the method 5 continues with block 50 in which the grown, selective dielectric layer is removed. An illustrative epitaxial layer stack 3 subsequent to the dielectric layer removal process of block 50 is shown in FIG. 12. It should be appreciated that the sidewall dielectric layer 260 can be removed using any etching process that is selective to the material used in the high-K dielectric layer 280. This removal process of block 50 leaves the sidewall of the epitaxial layer 130 exposed as illustrated in FIG. 12.

Referring again back to FIG. 2A, after the dielectric layer removal process of block 50, the method 5 continues with block 55 in which another epitaxial extension is grown on the other doped epitaxial layer from which the selective dielectric was removed in block 50. For example, as shown in FIG. 13, an epitaxial extension 290 can then be grown on this exposed sidewall similar to the process used to grow epitaxial extension 270. In some embodiments, the epitaxial extension 290 can be made of SiAs, SiP, SiB, SiGeB, GeB, GeSnB, or combinations thereof, and can be the same as—or different from—the material used in epitaxial layer 130.

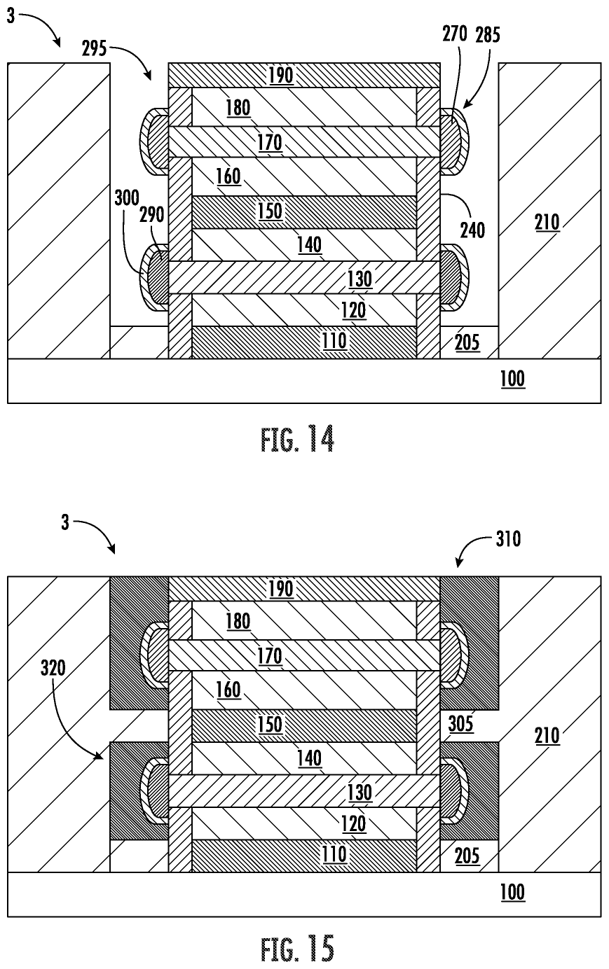

Referring back to FIG. 2A, after the epitaxial extension growth process of block 55, the method 5 continues with block 60 of FIG. 2B in which the high-K dielectric layer is removed and the epitaxial extensions are subsequently silicided. The high-K dielectric layer 280 can then be removed using any suitable selective etching process. It should be appreciated that after the high-K dielectric layer 280 is removed, the epitaxial extension 270 extends from the sidewall of epitaxial layer 170 and the epitaxial extension 290 extends from the sidewall of epitaxial layer 130. The exposed portions of the epitaxial extensions 270 and 290 are then silicided by selectively depositing a metal and then heating the deposited metal to form a salicide structure. An illustrative epitaxial stack layer 3 subsequent to the processing of block 60 is shown in FIG. 14. As shown, a salicide layer 285 has been formed on the epitaxial extension 270 and a salicide layer 300 has been formed on the epitaxial extension 290.

Referring back to FIG. 2B, after the silicide processing of block 60, the method 5 continues with block 65 in which a metal layer is deposited and etched. These metal layers are deposited so as to form contacts that connect with the salicide layers 285 and 300 as shown in the illustrative epitaxial stack layer 3 of FIG. 15. In the processing of block 65, a first metal layer is deposited to fill the void 295 (see FIG. 14) where the isolation layer 210 has previously been removed. The first metal layer is then etched and the upper part of the first metal layer is removed so a first metal contact 320 is formed (for the bottom transistor structure).

Referring back to FIG. 2B, after the metallization process of block 65, the method 5 continues to block 70 in which other metal layer is deposited and etched for the other transistor structure. It should be appreciated that the epitaxial stack layer 3 includes another void above the first metal contact 320 after the removal of the first metal layer above the first metal contact 320 and in which the isolation layer 210 is not present. As such, in block 70, that void is filled with a dielectric layer and then etched back to form a dielectric layer 305, as shown in FIG. 15.

Subsequently, in block 75 of the method 5 of FIG. 2B, the metal contact formation process of block 65 is repeated for the other transistor structure (illustratively the top transistor structure) as shown FIG. 15. To do so, a second metal layer is deposited in the remainder of the isolation void 295 and then etched back (or planarized) so a second metal contact 310 is formed (for the top transistor structure).

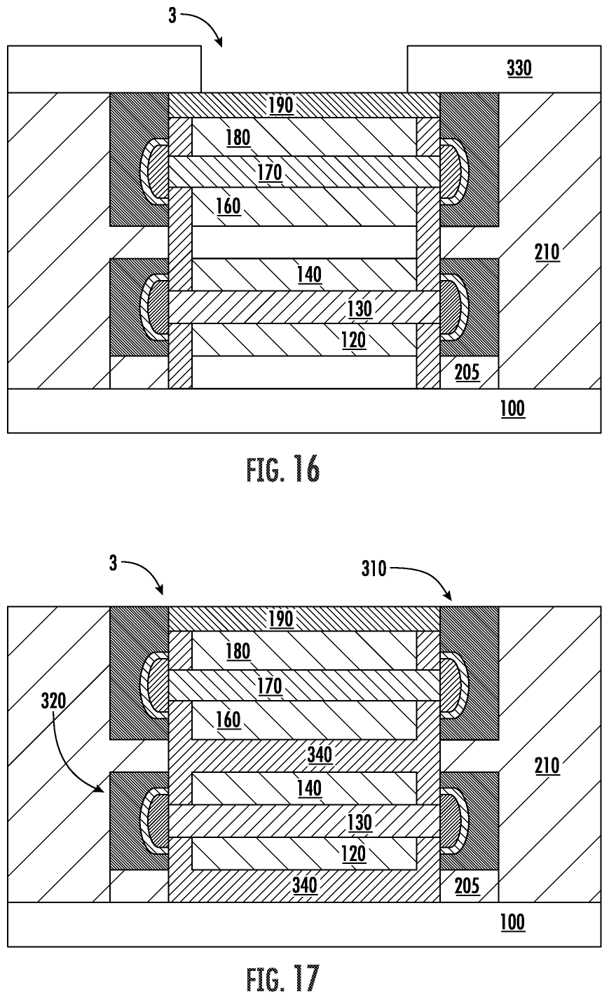

Referring back to FIG. 2B, after the metallization process of block 75, the method 5 continues to block 80 in which a mask and etch process is used to remove portions of the isolation dielectric adjacent the undoped epitaxial layer and the undoped epitaxial layer is subsequently removed and filled with a dielectric layer. Such a removal process can be performed, for example, by depositing and patterning a photoresist material to form mask layer 330 as shown in FIG. 16. The mask layer 330 can be used to etch and remove portions of the isolation dielectric 210 that are adjacent to the epitaxial layers 110 and 150 (i.e., those portions on the sidewalls of the epitaxial layers 110 and 150 extending into and out of the plane shown in FIG. 16). Next, the epitaxial layers 110 and 150 are then removed by using a selective etching process to form the epitaxial layer stack illustrated in FIG. 16. Subsequently, the mask layer 300 is removed and the empty spaces or voids previously filled with epitaxial layers 110 and 150 are be filled with a dielectric layer 340 using a deposition process, as shown in FIG. 17. The dielectric layer 340 can be formed with the same or a different dielectric material than that used in sidewall dielectric layer 240.

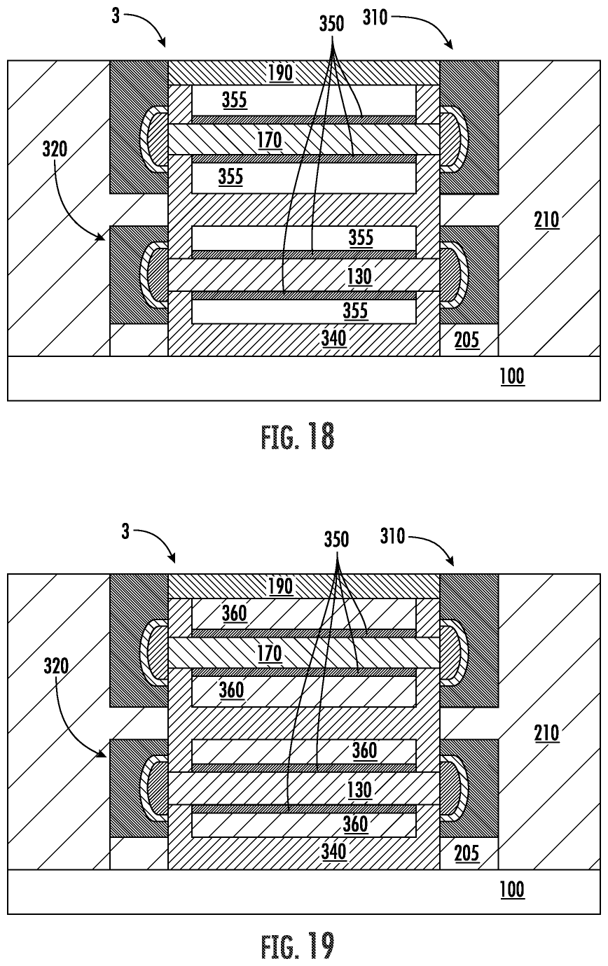

Referring back to FIG. 2B, after the dielectric filling process of block 80, the method 5 continues to block 85 in which the undoped/lightly doped epitaxial layers are removed and a high-K dielectric is deposited. For example, as shown in FIG. 18, the epitaxial layers 120, 140, 160, and 180 are removed . The removal process can be performed by depositing and patterning a photoresist material to form a mask layer (not shown). The mask layer can be used to etch and remove portions of the isolation dielectric 210 that are adjacent to the epitaxial layers 120, 140, 160, and 180 (i.e., those portions on the sidewalls of the epitaxial layers 120, 140, 160, and 180 extending into and out of the plane shown in FIG. 17). Next, the epitaxial layers 120, 140, 160, and 180 are removed by using a selective etching process. This mask is then removed, and a high-K dielectric layer 350 is selectively deposited on the exposed portions of the epitaxial layers 130 and 170, as shown in FIG. 18.

Referring again back to FIG. 2B, after the deposition of the high-K dielectric is deposited in block 85, the method 5 continues to block 90 in which a NMOS gate metal layer is deposited. Again, it should be appreciated that, after forming the high-K dielectric layers 350, gaps or voids 355 are present in the resulting structure, as shown in FIG. 18. The gaps 455 are subsequently filled with metal layers to form the gate metals in the corresponding transistor structure. For example, a first metal (for the NMOS gate) can first be selectively deposited into these gaps to form metal layers 360, as shown in FIG. 19.

Referring yet again back to FIG. 2B, after the NMOS gate metal layer deposition of block 90, the method 5 continues to block 95 in which the NMOS gate metal layer is partially etched and filled with a PMOS gate metal layer. To perform this process, the metal layer 360 is etched down to the middle of the dielectric layer 340 between the upper and lower transistor structures and subsequently filled with another metal layer 370 that will be used to make PMOS gate metal, as shown best in FIG. 1. According, the method 5 may be employed to fabricate the CFET semiconductor structure of FIG. 1, which includes a PMOS transistor located over the NMOS transistor as discussed above.

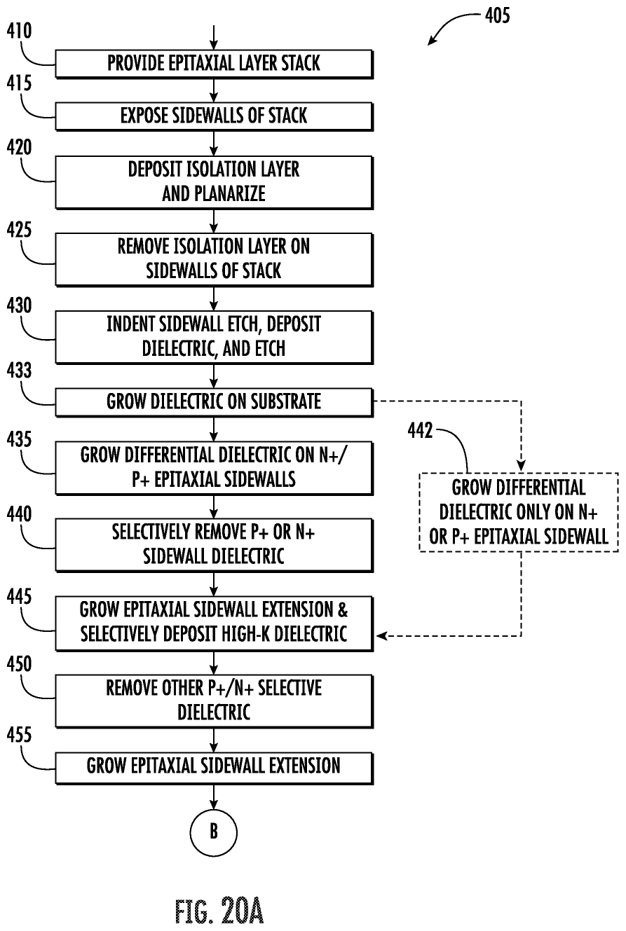

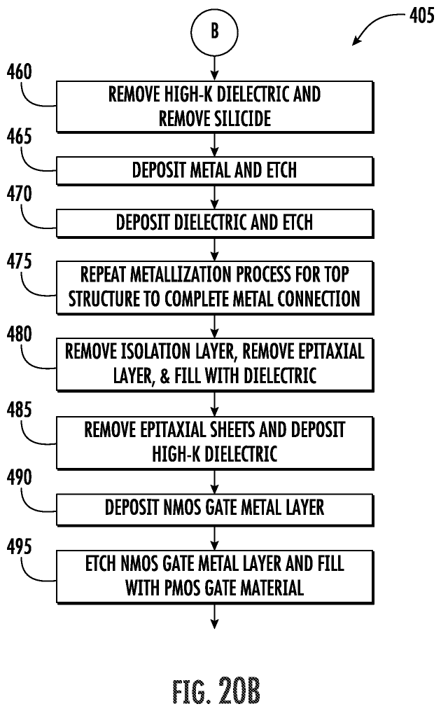

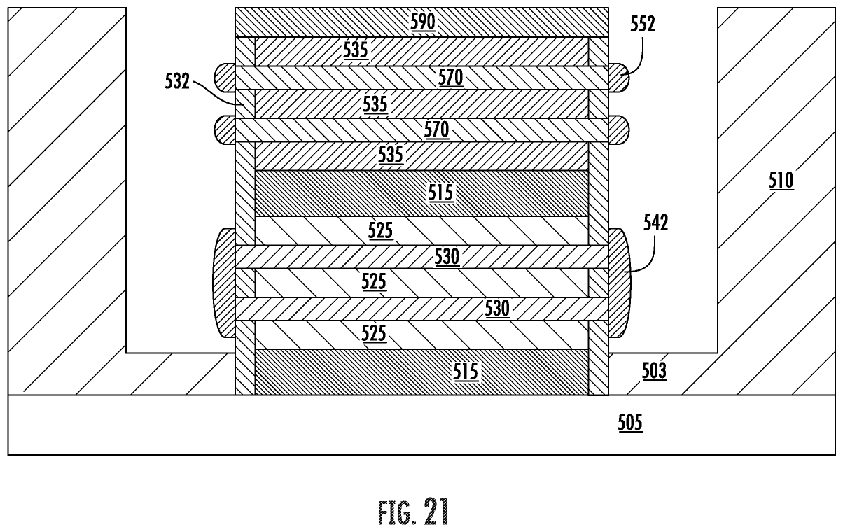

It should be appreciated that the methodology described above in regard to method 5 can be modified to manufacture CFET semiconductor devices having multiple channels. For example, a method 405 for fabricating a multichannel CFET structure is shown in FIGS. 20A & B. Some of the blocks of method 405 are identical or otherwise similar to corresponding blocks of the method 5. As such, in the description of method 405 below, some of the details of the similar blocks have been omitted for clarity of the present description; however, it should be appreciated that the description provided above with regard to similar blocks of method 5 are equally applicable to the similar blocks of method 405.

The method 405 beings with block 410 in which an epitaxial layer stack is fabricated or otherwise provided. It should be appreciated that the stack of epitaxial layers provided in block 410 contain more epitaxial layers than the epitaxial layer stack 3 provided in method 5 above because the final device will contain multiple channels for the NMOS transistor and multiple channels for the PMOS transistor. To do so, in the illustrative embodiment, following epitaxial layers are successively grown or deposited on a substrate 505 to create a stacked epitaxial structure: a base epitaxial layer 515, an un-doped/lightly doped epitaxial layer 525, an n+ doped epitaxial layer 530, an un-doped/lightly doped epitaxial layer 525, a n+doped epitaxial layer 530, un-doped/lightly doped epitaxial layer 525, a base epitaxial layer 515, an un-doped/lightly doped epitaxial layer 535, a p+ doped epitaxial layer 570, an un-doped/lightly doped epitaxial layer 535, a p+doped epitaxial layer 570, an un-doped/lightly doped epitaxial layer 535, and a cap layer 590 as shown in FIG. 21.

Subsequently, in block 415 of the method 405 of FIG. 20A, the sidewalls of the epitaxial stack are exposed by a masking and etching process. An isolation layer is then deposited and planarized, as indicated in block 420 of FIG. 20A. The isolation layer on the sidewalls of the epitaxial layer stack are then removed, as shown in block 425 of FIG. 20A, by using a mask and etching process. An indent etch process is then used to remove portions of the sidewalls of all of the un-doped/lightly doped epitaxial layers without removing the sidewalls of the highly doped epitaxial layers, as shown in block 430 of FIG. 20A. A dielectric layer is subsequently deposited and aligned etched to form dielectric sidewalls 532 on the un-doped/lightly doped epitaxial layers. Then, in block 433, another dielectric layer 503 is grown on the upper surface of the substrate 505 (between the isolation layer 510 and the dielectric sidewall of 532 formed on the sidewall of the bottom base epitaxial layer 515).

Subsequently, in block 435, a differentially-sized dielectric growth is then performed on the highly-doped epitaxial layers 530 and 770 (that will be used to form the multiple channels in the transistors) of the epitaxial stack. The sidewall dielectric layers are selectively grown so that they have different sizes. It should be appreciated that such a structure is possible because the oxidation rate of the material in epitaxial layer 530 can be different than the oxidation rate of the material in epitaxial layer 570. For example, as shown in FIG. 21, the sidewall dielectric layer 542 for epitaxial layer 530 is larger than the sidewall dielectric layer 552 for epitaxial layer 570. In some embodiments, the oxidation rate can be different because of the materials (Si or Ge) used in these two epitaxial layers. In other embodiments, though, the oxidation rate can be different because of the dopant used (n or p) in these two epitaxial layers. In yet other embodiments, the oxidation rate can be different because a combination of these two factors (dopant and material).

Referring now back to FIG. 20A, after differentially-sized dielectric growth process of block 435, the method 405 continues to block 440 in which one of the differentially-sized dielectric layer is removed. For example, with regard to the structure of FIG. 21, the sidewall dielectric layer 552 is removed. This process can be performed by an etching process that is selective to the dopant/material of the sidewall dielectric layer 552 which is different than the dopant/material of the sidewall dielectric layer 542.

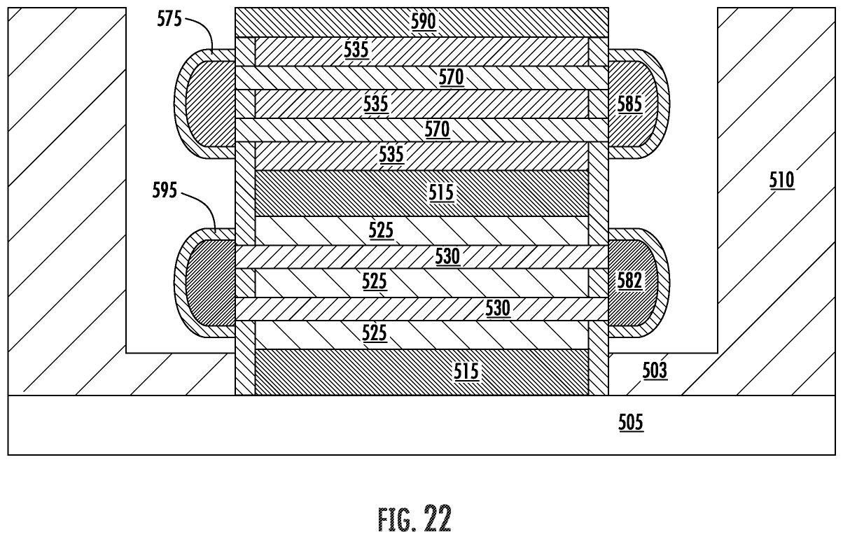

Referring back to block 433 of the method 405 of FIG. 20A and alternative to blocks 435 and 440, the method 405 may continue from block 433 to block 442 in which an epitaxial extension is grown on one of the highly doped epitaxial layers without growing an extension on the other highly doped epitaxial layer. Subsequently, an epitaxial extension is grown on the highly doped epitaxial layers. For example, as shown in FIG. 22, an epitaxial extension 585 is grown on the exposed sidewall of epitaxial layer 570. Once the epitaxial extension has been formed, a high-K dielectric layer (not shown) is selectively deposited on just that epitaxial extension 585, as shown in block 445 of FIG. 20A.

In block 450 of FIG. 20A, the grown, selective dielectric is removed. For example, the sidewall dielectric layer 542 (shown in FIG. 21) can be removed by a selecting etching process. In block 455, another epitaxial extension is grown on the highly doped epitaxial layer where the selective dielectric layer was removed. For example, as shown in FIG. 22, an epitaxial extension 582 is grown on the exposed sidewall of epitaxial layer 530.

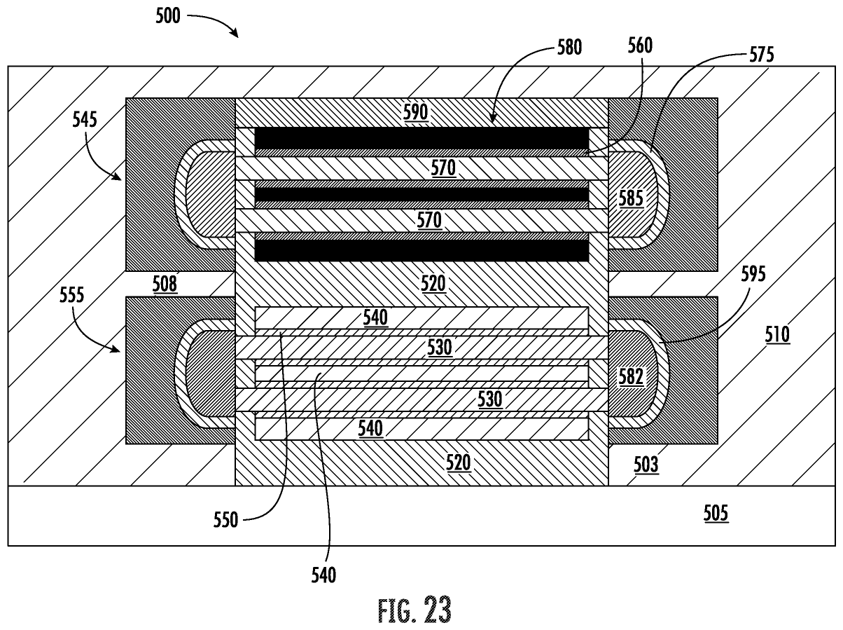

Subsequently, in block 460 of the FIG. 20B, the high-K dielectric layer is removed and the epitaxial extensions are then silicided. For example, the epitaxial extensions 582 and 585 can then be silicided to form a salicide layer 575 on the epitaxial extension 585 and a salicide layer 595 on the epitaxial extension 582, as shown in FIG. 22. Next, in block 465 of the method 405 of FIG. 20B, a metal layer is deposited and etched to form the metal contact layer 555 (see FIG. 22). In block 470, a dielectric layer deposition and etch is performed to form a dielectric layer 508 (see FIG. 23). The metal deposition and etch process is then repeated for the top structure in block 475 to form the metal contact layer 545 and complete the metal connections. A mask and etch process is then used to remove portions of the isolation dielectric 510 adjacent the base epitaxial layers 515. Subsequently, in block 480 of FIG. 20B, the base epitaxial layers 515 are removed and filled with a dielectric layer to form the dielectric structure 520 as shown in FIG. 23. Next, in block 485 of FIG. 20B, the undoped/lightly doped epitaxial layers are removed and a high-K dielectric deposited to form the high-K dielectric layers 550 and 560 as shown in FIG. 23. In block 490 of FIG. 20B, a NMOS gate metal layer is then deposited to form NMOS the gate metal layers 540 as shown in FIG. 23. And, in block 495 of FIG. 20B, the NMOS gate metal layer is partially etched back and then filled with a PMOS gate metal layer to form the PMOS ate metal layers 580 as shown in FIG. 23.

The final CFET device 500 formed by performance of the method 405 is shown in FIG. 23. The CFET device 500 contains a lower, dual-channel NMOS transistor structure and an upper, dual-channel PMOS transistor structure.

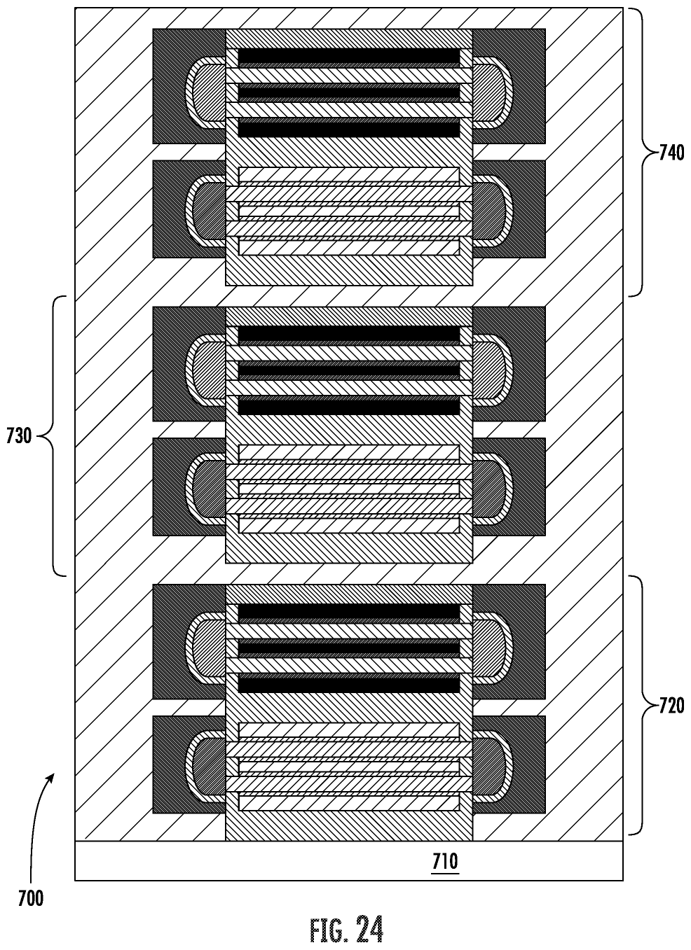

It should be further appreciated that the method 5 and 405 described above may be further modified to fabricate CFET semiconductor devices having more than just two transistor structures, each of which is vertically stacked with respect to each other. For example, as shown in FIG. 24, a CFET semiconductor device 700 having multiple transistor structures may be fabricated. In such embodiments, the CFET semiconductor device 700 includes a substrate 710 with a first set 720 of PMOS and NMOS dual-channel transistors, a second set 730 of PMOS and NMOS dual-channel transistors, and a third set 740 of PMOS and MNOS dual-channel transistors in a vertical configuration. Although FIG. 24 shows that the CFET semiconductor device 700 includes transistor structures that have multiple channels, one or more of the transistor structures could be manufactured with just a single channel.

The methods and semiconductor devices described herein may include any one or more of the following features. First, the described methods use substantially uniformly-doped epitaxial layers to make self-aligned, selective epitaxial extensions that can be used as source/drain regions in 3D semiconductor devices. Second, the methods allow differential oxide growth on the sidewalls of substantially uniformly-doped epitaxial layers by using different doping types and/or different semiconductor materials in the epitaxial layer. For example, these epitaxial layers can contain the same type of semiconductor material but with different dopant types (i.e., Si doped with for NMOS and Si doped with boron for PMOS), different semiconductor materials (Si for NMOS and Ge for PMOS) or different semiconductor types and different dopant types (i.e., Si doped with As for NMOS and SiGe doped with boron for PMOS). These allow a 3D CFET device to be manufactured using epitaxially-grown and uniformly-doped channels that also have differential channel oxide extension growths. A third feature is that the stack spacing between adjacent source and drain regions may be grown together to connect multiple channels. This will tend to increase the normalized saturation drain current (Idsat) to meet the circuit requirements in 3D semiconductor devices. A fourth feature is that these methods can manufacture a 3D semiconductor device with fewer process steps for 3D stacking since all the NMOS source/drain regions may be grown at substantially the same time and all the PMOS source/drain regions may be grown at substantially the same time without using any photoresist mask. These features may enable higher density 3D semiconductor devices to be produced at a reduced cost.

While the disclosure has been illustrated and described in detail in the drawings and foregoing description, such an illustration and description is to be considered as illustrative and not restrictive in character, it being understood that only illustrative embodiments have been shown and described and that all changes and modifications that come within the spirit of the disclosure are desired to be protected.

There are a plurality of advantages of the present disclosure arising from the various features of the methods, apparatuses, and systems described herein. It will be noted that alternative embodiments of the methods, apparatuses, and/or systems of the present disclosure may not include all of the features described yet still benefit from at least some of the advantages of such features. Those of ordinary skill in the art may readily devise their own implementations of the methods, apparatuses, and systems that incorporate one or more of the features of the present invention and fall within the spirit and scope of the present disclosure as defined by the appended claims.

1. A method of making a semiconductor device, comprising:
growing a first epitaxial layer over a substrate;
growing a second epitaxial layer over the first epitaxial layer, the second epitaxial layer having an oxidation rate different than the first epitaxial layer;
exposing sidewalls of the first and second epitaxial layers;
growing a first epitaxial extension on the sidewall of the first epitaxial layer while insulating the sidewall of the second epitaxial layer;
growing a second epitaxial extension on the sidewall of the second epitaxial layer while insulating the sidewall of the first epitaxial layer;
forming a first contact on the first epitaxial extension; and
forming a second contact on the second epitaxial extension.

2. The method of claim 1, wherein the first epitaxial layer comprises a first conductivity type dopant and a first semiconducting material and the second epitaxial layer comprises a second semiconducting material different from the first semiconducting material or a second conductivity type dopant different from the first conductivity type dopant.

3. The method of claim 1, wherein growing the first epitaxial extension comprises growing a first sidewall dielectric layer on the sidewall of the first epitaxial layer, and
wherein growing the second epitaxial extension comprises growing a second sidewall dielectric layer on the sidewall of the second epitaxial layer, wherein the first and second sidewall dielectric layers have a different size or thickness.

4. The method of claim 1, wherein growing the first epitaxial extension further comprises removing the first sidewall dielectric layer from the first epitaxial layer prior to growing the first epitaxial extension.

5. The method of claim 4, wherein growing the first epitaxial extension further comprises forming a high-K dielectric layer on the first epitaxial extension prior to growing the second epitaxial extension.

6. The method of claim 5, further comprising:
removing the high-K dielectric layer from the first epitaxial extension after growing the second epitaxial extension; and
growing a first salicide on the first epitaxial extension and a second salicide on the second epitaxial extension.

7. The method of claim 6, further comprising:
depositing a first source metal and a first drain metal to connect with the first salicide; and
depositing a second source metal and a second drain metal to connect with the second salicide.

8. The method of claim 7, further comprising insulating the first and second epitaxial layers.

9. The method of claim 8, further comprising:
forming a first gate metal to create a first transistor comprising the first epitaxial layer; and
forming a second gate metal to create a second transistor comprising the second epitaxial layer, wherein the second transistor is located over the first transistor.

10. The method of claim 1, wherein the first epitaxial layer comprises Si heavily doped with an n-type dopant and the second epitaxial layer comprises Ge heavily doped with a p-type dopant.

11. A method of making a semiconductor device, comprising:
growing a stack of epitaxial layers over a substrate, wherein the stack of epitaxial layers includes a first epitaxial layer and a second epitaxial layer over the first epitaxial layer, the second epitaxial layer being different than the first epitaxial layer;
depositing an isolation barrier around the stack of epitaxial layers to cover at least a sidewall of each epitaxial layer of the stack of epitaxial layers;
removing a portion of the isolation barrier to expose the sidewalls of the epitaxial layers in the stack of epitaxial layers;
differentially growing a dielectric on the sidewall of the first epitaxial layer and the second epitaxial layer;
removing the dielectric from the sidewall of the first epitaxial layer;
growing a first epitaxial extension on the sidewall of the first epitaxial layer;
removing the dielectric from the sidewall of the second epitaxial layer after growing the first epitaxial extension;
growing a second epitaxial extension on the sidewall of the second epitaxial layer;
forming a first salicide layer on the first epitaxial extension and a second salicide layer on the second epitaxial extension;
forming first source and drain contacts to the first salicide and forming second source and drain contacts to the second salicide; and
depositing a first gate metal to form a first transistor and depositing a second gate metal to form a second transistor over the first transistor.

12. The method of claim 11, wherein the first epitaxial layer comprises a first conductivity type dopant and a first semiconducting material and the second epitaxial layer comprises a second semiconducting material different from the first semiconducting material or a second conductivity type dopant different from the first conductivity type dopant.

13. The method of claim 11, wherein growing the first epitaxial extension comprises growing a first sidewall dielectric layer on the sidewall of the first epitaxial layer, and wherein growing the second epitaxial extension comprises growing a second sidewall dielectric layer on the sidewall of the second epitaxial layer, wherein the first and second sidewall dielectric layers have a different size or thickness.

14. The method of claim 11, wherein growing the first epitaxial extension further comprises removing the first sidewall dielectric layer from the first epitaxial layer prior to growing the first epitaxial extension.

15. The method of claim 14, wherein growing the first epitaxial extension further comprises forming a high-K dielectric layer on the first epitaxial extension prior to growing the second epitaxial extension.

16. The method of claim 15, further comprising:
removing the high-K dielectric layer from the first epitaxial extension after growing the second epitaxial extension; and
growing a first salicide on the first epitaxial extension and a second salicide on the second epitaxial extension.

17. A complementary field effect transistor (CFET) semiconductor device, comprising:
a substrate;
a lower transistor stacked over the substrate, the lower transistor comprising:
a first channel formed from an epitaxial layer comprising a first conductivity type dopant,
first self-aligned source and drain extension regions that have been grown from the sidewalls of the first channel,
a first salicide layer connected to the first self-aligned source and drain extension regions,
first source and drain contacts connected to the first salicide layer, and
a first gate metal layer;
an upper transistor stacked over the lower transistor, the upper transistor comprising:
a second channel formed from an epitaxial layer comprising a second conductivity type dopant being different than the first conductivity type dopant,
second self-aligned source and drain extension regions that have been grown from the sidewalls of the second channel,
a second salicide layer connected to the second self-aligned source and drain extension regions,
second source and drain contacts connected to the second salicide layer,
a second gate metal layer; and
a dielectric layer and an isolation layer insulating the lower transistor and the upper transistor.

18. The device of claim 17, wherein the first channel comprises Si and the second channel comprises Ge.

19. The device of claim 17, wherein the lower transistor comprises multiple first channels and multiple second channels.

20. The device of claim 17, further comprising a third transistor stacked over the upper transistor, the third transistor comprising:
a third channel formed from an epitaxial layer comprising the first conductivity type dopant,
third self-aligned source and drain extension regions that have been grown from the sidewalls of the third channel,
a third salicide layer connected to the third self-aligned source and drain extension regions,
third source and drain contacts connected to the third salicide layer, and
a third gate metal layer; and
a fourth transistor stacked over the third transistor, the fourth transistor comprising:
a fourth channel formed from an epitaxial layer comprising the second conductivity type dopant,
fourth self-aligned source and drain extension regions that have been grown from the sidewalls of the fourth channel,
a fourth salicide layer connected to the fourth self-aligned source and drain extension regions,
fourth source and drain contacts connected to the fourth salicide layer, and
a fourth gate metal layer.
